(19) United States
(12) Patent Application Publication
(10) Pub. No.: US 2022/0388839 A1
(43) Pub. Date: Dec. 8, 2022

(54) Method for Creating Hydrophilic Surfaces or Surface Regions on a Substrate

(71) Applicant: Robert Bosch GmbH, Stuttgart (DE)

(72) Inventors: Volker Becker, Marxzell (DE); Franz Laermer, Weil Der Stadt (DE); Daniel Pantel, Mundelsheim (DE)

(21) Appl. No.: 17/770,561

(22) PCT Filed: Oct. 12, 2020
(86) PCT No.: PCT/EP2020/078617

§ 371 Date: Apr. 20, 2022

(30) Foreign Application Priority Data
Oct. 25, 2019 (DE) 10 2019 216 438.2

(51) Int. Cl. B81C 1/00; B01L 3/00

(52) U.S. Cl. CPC B81C 1/00206; B01L 3/502707; B01L 2200/12; B01L 2300/161

(57) ABSTRACT

In a method for creating hydrophilic surfaces or surface regions on one or more silicon surfaces of a substrate, a vapour phase of hydrogen peroxide is generated in a reactor by heating an aqueous hydrogen peroxide solution. The substrate having the silicon surface or surfaces to be treated is exposed to the vapour phase, whereby a hydrophilisation of the silicon surfaces in achieved.

The present invention relates to a method for creating hydrophilic surfaces or surface regions on one or more silicon surfaces of a substrate and to a substrate which can be produced by this method.

### STATE OF THE ART

For example in connection with silicon microarray chips for lab-on-chip applications, often high-grade hydrophilic silicon surfaces are required which allow as good as possible wetting or filling of structures of the substrate with aqueous media. Such a silicon microarray may include, for example an arrangement of small so-called trench cells which are etched in the silicon chip. These trench cells, which may be etched into the silicon crystal in particular by reactive ion etching, form compartments within the microarray in which different reactions may proceed independently of one another. For example, the compartments may be provided for carrying out one or more PCR reactions. The silicon surfaces of the substrate or especially the individual trench cells are thus made functional using suitable means. Depending on application, in particular a hydrophobic and/or lipophobic design of individual surfaces or also of the entire surface of the silicon chip may be necessary. This may be realized, for example in the form of a fluorinated (photo) lacquer surface which is repellent to aqueous (and oily) solutions. A lacquer surface thus fluorinated is thus hydrophobic and lipophobic, but for fluorocarbons, such as for example FC-40 or FC-77, highly attracting so that coating with fluorocarbons and good insulation of the trench cells with respect to one another during the workflow in the microarray is possible. The interior of the trench cells itself should on the other hand be high-grade hydrophilic so as to attract aqueous solutions as well as possible so that, for example reliable spotting with polyethylene glycol, aqueous media or similar materials and the actual “biocontent”, such as for example certain PCR primers and/or enzymes in aqueous solution, may take place in the preliminary process or when filling with the, for example PCR master mix/eluate in aqueous phase during the lab-on-chip workflow.

Hydrophilization of the trench cells or generally of regions and/or compartments within the microarray during or after the production process of the substrate is not without problems. It is known, for example to hydrophilize the trench cells by initially fluorinating the silicon surfaces by means of a CF4 plasma. This fluorination is also used conventionally to convert the resulting lacquer surface on the silicon substrate into a Teflon-like material by substitution of protons with fluorine free radicals. For polymers, this fluorination of the surface is irreversible, that is, the fluorine atoms which have been incorporated into the polymer structure are also not substituted by subsequent moistening of the polymer surface. On the other hand, water or moisture or air moisture on a fluorinated silicon surface subsequently replaces the fluorine groups with OH groups and provides a largely hydrophilic silicon surface. However, this method leaves behind fluorine or HF (hydrogen fluoride), which is bound to the silicon surface, on the silicon surfaces so that hydrophilization is not perfect and the substrate surface is not completely free of impurities.

In a further approach, silicon surfaces are hydrophilized by an oxygen plasma in a so-called O₂ plasma stripper by oxidation and subsequent contact with moisture or air moisture. However, this method suffers from the fact that the oxygen free radicals required for the oxidation reaction from the O₂ plasma are very short-lived and therefore have only a short diffusion range, above all in trench channels with high aspect ratio of depth to diameter. Therefore, for example lower-lying silicon regions in trench cells cannot be reached easily. In addition, a longer O₂ plasma process leads to previously created Teflon-like chip surfaces being able to be reoxidized and hence losing the required hydrophobic (and/or lipophobic) character again. Use of ozone gas (O₃) would also have a similarly damaging effect on the lacquer surface and oxidize or even wear away the hydrophobic (and/or lipophobic) surface lacquer in an undesirable manner.

Furthermore, the use of strongly oxidizing chemicals is known, such as for example mixtures of concentrated sulfuric acid and hydrogen peroxide (“piranha clean”), red fuming nitric acid, hydrochloric acid/hydrogen peroxide/water mixtures or ammonia/hydrogen peroxide/water mixtures. These chemicals may also in principle damage the lacquer surface or oxidize it and/or lead to peeling from the chip surface. Furthermore, it is difficult to introduce these chemicals into the interior of the initially still hydrophobic trench cells so that now as before, there is a need for an effective method for hydrophilizing surfaces, in particular inner surfaces of trench cells, in particular of trench cells with high aspect ratio (depth:diameter), in particular for a structured substrate with silicon surfaces.

### DISCLOSURE OF THE INVENTION

### Advantages of the Invention

The proposed method serves to create hydrophilic surfaces or surface regions on one or more silicon surfaces of a substrate. A vapor phase of hydrogen peroxide is thus created in a reactor by heating an aqueous solution of hydrogen peroxide. The substrate with the silicon surface or surfaces is introduced into this vapor phase or exposed to the vapor phase. This leads to effective hydrophilization of the silicon surfaces. The proposed method thus allows perfect hydrophilization, for example of the interior of trench cells or also of free silicon surfaces. Optionally existing lacquer surfaces are thus not damaged and in particular not worn away or oxidized. In particular, for example fluorinated lacquer surfaces in the sense of a Teflon-like surface layer are not attacked, damaged or oxidized so that these surfaces unrestrictedly retain the strongly pronounced hydrophobic and lipophobic behavior due to the preceding Teflon-like application. On the other hand, an extreme degree of hydrophilization is achieved on free silicon surfaces by the proposed method. Hence, in particular trench cells may be hydrophilized in a particularly advantageous manner so as to form high affinity for aqueous solutions or, for example PEG-containing solutions or PEG (PEG—polyethylene glycol), which is necessary, for example for applications with PCR reactions or the like. Using the proposed method, substrates with silicon surfaces (for example silicon wafers), which are provided, for example as microarrays for a PCR application in a lab-on-chip environment, may thus be hydrophilized very effectively by reaction of hydrogen peroxide vapor.

The hydrophilic surfaces which can be created by the proposed method can be investigated, for example using the contact angle measuring method known per se, in which water droplets are applied to a surface to be investigated and their behavior characterized and measured. The inventors could show that the surfaces hydrophilized by the proposed method in this contact angle measuring method produce measured values about 0°, for example <0.5°. This is a significant improvement in the hydrophilization of silicon surfaces with respect to traditional techniques in which measured values between 5° and 10° are usually achieved.

In a particularly advantageous design of the method, the substrate is heated to a temperature which lies above the temperature of the heated hydrogen peroxide solution. The temperature of the substrate is preferably higher by 1-10° C., particularly preferably by 1-5° C., than the temperature of the heated hydrogen peroxide solution. For example a temperature of the substrate increased by 3° C. with regard to the heated hydrogen peroxide solution is sufficient and effective. To carry out the method, the aqueous hydrogen peroxide solution is brought to an increased temperature in a reactor so as to create an adequate vapor phase in the reactor. The substrate to be treated may be introduced into the reactor before, after or during heating of the hydrogen peroxide solution. The temperature of the substrate in the reactor is advantageously set by heating so that it is higher, in particular slightly higher, than the temperature of the hydrogen peroxide solution or the vapor phase. It is thus ensured that no condensation occurs on the substrate surface. The hydrophilization process is thus to an extent a semi-dry process in which excellent hydrophilization results of the silicon surfaces are also achieved in particular in the interior of the compartments or trench cells of a substrate or microarray. This leads to a significant improvement in subsequent filling of the microarrays with aqueous media. In this semi-dry method, the surfaces of the substrate and for example the trench cells do not become wet or are not moistened by liquid droplets. This is very advantageous, for example in connection with self-supporting, filigree structures of the substrate (MEMS structures—Micro Electro-Mechanical System) which are to be hydrophilized subsequently. All in all the proposed method may therefore be used advantageously not only for lab-on-chip applications, but is also generally an extension of the process spectrum in silicon surface micromechanics.

The hydrogen peroxide solution is preferably heated to a temperature between 30° C. and 90° C., in particular in the range between 40° C. and 60° C., preferably to 45° C. The long-term stability of the hydrogen peroxide solution is thus higher, the lower the selected temperature of the hydrogen peroxide solution. At higher temperature of the solution, the long-term stability decreases gradually. At the upper limit of 90° C., lower stability of the solution thus has to be expected than at 60° C. or 45° C. or 30° C., but also there are benefits from significantly increased corrosiveness of the vapor mixture with respect to all types of contaminants and an increased hydrophilization effect, firstly due to the higher chemical corrosiveness according to the Arrhenius law, secondly as a result of the higher vapor pressure and hence higher density of the reactive hydrogen peroxide species in the vapor phase. In this sense, a mutual dependency exists here between required corrosiveness and purification effect and rate of hydrophilization at as high as possible a temperature on the one hand, and required long-term stability at as low as possible a temperature on the other hand.

The hydrogen peroxide solution may be, for example a 5-85% strength aqueous solution. A 30% strength solution, which is available commercially and cost-effectively under the designation “perhydrol”, is particularly preferred. In principle higher-percentage hydrogen peroxide solutions may also be used, for example an 85% strength hydrogen peroxide solution, as customary for example as oxidizer in rocket engines. However, the increasing danger of concentrated mixtures should be noted in such higher-concentrated solutions. Since very good results are already achieved even using a 30% strength solution, such solutions are particularly preferred since handling thereof is largely safe and they are available cost-effectively as standard mixtures.

To carry out the method, the surfaces of the substrate to be treated are introduced into the reactor with the vapor phase of the hydrogen peroxide solution or are located therein even during creation of the vapor phase. It is thus particularly preferred if the surfaces to be treated are orientated downwards (“face-down”) so that the surfaces to be treated come into contact with the vapor phase in a particularly effective manner. In principle it is also possible that the substrate is introduced into the reactor at a different orientation. A reactor known per se may be used for this with particular advantage, as is known, for example from DE 197 04 454 A1 in connection with hydrogen fluoride vapor etching of silicon substrates in sacrificial layer etching technology. A conventional heating device may be provided in the wall of the reactor to heat the hydrogen peroxide solution. For example cover heating may be provided in the reactor to heat the substrate. The substrate may thus be suspended or clamped in a corresponding mounting of the cover before the cover with cover heating is placed on the reactor. Conventional heating elements may be used as heating for the substrate. The substrate is thus brought to the required temperature. Effective hydrophilization of the silicon surfaces to be treated is effected by contact with the vapor phase in the reactor. The treatment period necessary for this is, for example between 5 minutes and 20 minutes. Effective hydrophilization may be achieved, for example even with a treatment period of 10 minutes. Depending on application and design of the substrate, shorter or longer treatment periods may be useful. During the reaction time, the silicon surfaces of the substrate are exposed to the hydrogen peroxide-steam mixture, thus oxidized and hydrophilized. After for example 10 minutes, complete hydrophilization and purification of the silicon surfaces is usually already achieved. The hydrogen peroxide thus reacts relatively corrosively with respect to silicon and typical contaminants at the increased temperatures so that they may be dissolved on contact with the aqueous vapor phase. Since in this reaction, different from sacrificial layer etching of silicon dioxide, for example by HF vapor, no water of reaction is formed, also no water of reaction has to be removed from the substrate surface by thermal evaporation. Against this background, the temperature difference between the hydrogen peroxide bath and the substrate surface may be kept very low in the range of a few ° C. It is thus particularly advantageous if the substrate temperature is only slightly warmer than the hydrogen peroxide bath, since thus condensation on the silicon surface with the formation of droplets may be ruled out. Such droplet formation may optionally be disadvantageous since, for example for filigree MEMS structures, irreversible adhesion (so-called “sticking”) may thus occur on the surface. In addition, droplets of moisture on the surfaces leave behind dried edges which are at least a visual problem.

In a particularly preferred design of the method, the substrate is a silicon microarray wafer which has different regions or compartments which may be hydrophilized specifically by the proposed method. The silicon microarray wafer preferably has one or more trench cells, that is, etched structures with particularly high aspect ratio (depth:diameter) which may be used, for example as compartments for carrying out different, for example biochemical reactions, for example in connection with PCR reactions. The substrate is particularly advantageously a microfluidic device, in particular a microfluidic device for lab-on-chip applications. Such microfluidic devices are particularly suitable, for example for automated carrying out of different reactions, for example in connection with molecular diagnostic methods.

It is a particular advantage of the proposed method that the interior of trench cells, in particular the interior of trench cells with a high aspect ratio (ratio of depth to diameter) may thus also be reached. In this respect, the proposed method is particularly suitable for “deep” trench cells. This depends above all on the fact that the hydrogen peroxide species, also and above all in the vapor phase, are very long-lived and stable so that they penetrate deep into the trench cells and become active only on contact with their surfaces. A reaction or a loss of hydrogen peroxide species only takes place on contact with the surfaces which lead to hydrophilization. Different from, for example the case of O₂ free radicals, in which a loss of species takes place even in the event of collision of the free radicals from the plasma with one another so that their range is very limited, an almost unlimited range within the framework of the reactor exists in the hydrogen peroxide vapor of the proposed method.

Optionally required masking of the surfaces which are not to be hydrophilized may be realized, for example by a photolacquer or by other dielectric layers, such as for example silicon nitride (SiN) so that only the free silicon is hydrophilized.

The invention furthermore includes a substrate having hydrophilic surfaces or hydrophilic surface regions which can be produced by the described method. With regard to further features of this substrate, reference is made to the above description. All in all extremely hydrophilic properties of the silicon surfaces treated accordingly may be achieved by the proposed method so that subsequent filling of substrates pretreated in this way (for example a lab-on-chip microarray) is considerably improved.

Further features and advantages of the invention can be seen from the following description of examples in conjunction with the drawings. The individual features may thus be realized respectively in themselves or in combination with one another.

In the drawings:

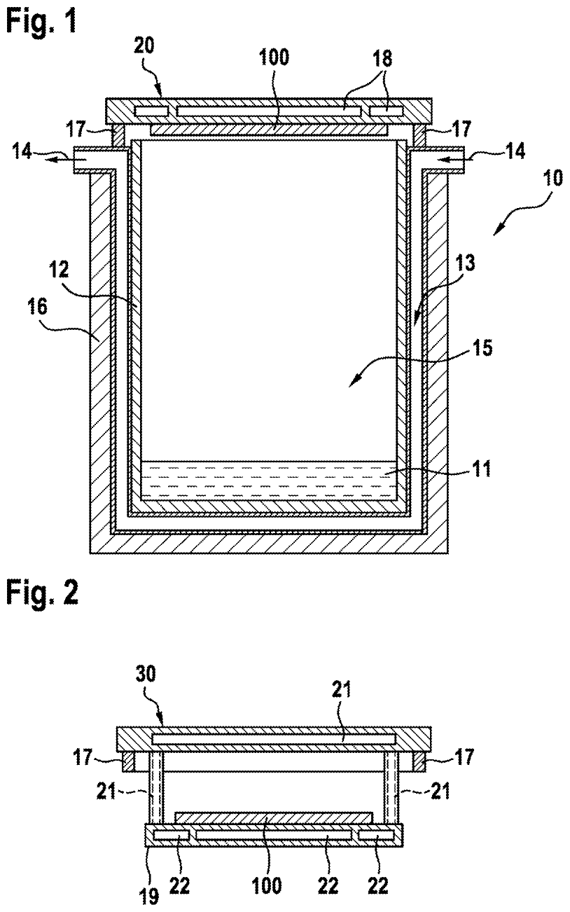

FIG. 1 shows a sectional representation through a reactor known per se which is suitable for carrying out the proposed method and

FIG. 2 shows a sectional representation of a further design of a cover for a reactor according to FIG. 1.

### DESCRIPTION OF EXAMPLES

FIG. 1 shows in a sectional representation, a reactor in which an aqueous hydrogen peroxide solution 11 is introduced. The substrate 100 with the silicon surfaces to be treated is inserted in the cover 20 of the reactor. The aqueous hydrogen peroxide solution is located in a container 12 within the reactor, wherein the container 12 is surrounded by a heating jacket 13. The heating jacket allows heating of the aqueous hydrogen peroxide solution 11 by means of a heating medium (arrow 14) flowing through the heating jacket 13, for example water in a heating circuit. Of course other heating methods are also possible. By heating the container 12, a homogeneous vapor phase 15 of hydrogen peroxide is created within the container 12. The reactor 10 is sealed towards the outside by an insulation jacket 16 so that the temperature within the container 12 is kept constant. The cover 20 of the reactor 10 is furnished with seals 17 which are in particular resistant to the hydrogen peroxide vapor 15. A heating device 18 is located in the cover 20 so that the substrate 100 (silicon substrate) fixed on the inner side of the cover 20 may be heated to the required temperature.

FIG. 2 shows a further possible design of the cover 30 of the reactor 10. The substrate 100 is thus not arranged, for example clamped, headfirst as in FIG. 1 against an upper heating device 18, but placed on a heating plate located therebelow as heating device 19 which is connected to the upper part of the cover 30 via bars 21. The heating plate 19 is heated via heating devices 22.

The arrangement of the substrate 100 with the silicon surfaces to be treated may thus be arranged downwards with the aid of the cover 20 according to FIG. 1 in a particularly simple manner with orientation of the surfaces to be treated in the direction of the vapor phase 15 or with the surfaces to be treated, wherein the substrate 100 is clamped, for example by means of suitable clamps or the like. On the other hand, it is also possible to place the substrate 100 on a heating plate 19 of a cover 30 in the design according to FIG. 2 so that the surfaces of the substrate 100 to be treated are indeed orientated upwards, but nevertheless may be freely flooded by the vapor phase 15.

To actually carry out the method, the aqueous hydrogen peroxide solution 11 is heated, for example to a temperature between 30° C. and 90° C., preferably to a temperature between 40° C. to 60° C., for example to 45° C. A standardized 30% strength so-called “perhydrol” solution may be used with particular advantage as aqueous hydrogen peroxide solution. In the temperature range between 30° C. and 90° C., in particular between 40° C. and 60° C. and preferably at 45° C., the hydrogen peroxide solution has sufficient long-term stability and may be used without considerable change in concentration over a longer residence time in the reactor 10. Heating of the hydrogen peroxide solution 11 effects the creation of the vapor phase 15 from hydrogen peroxide and steam. Even before or also after creation of the vapor phase, the substrate 100 is placed in the reactor 10 either headfirst, for example according to the design of the cover 20 from FIG. 1 or with the surfaces to be treated upwards according to the design of cover 30 in FIG. 2 and brought to a temperature, which preferably lies above the temperature of the aqueous hydrogen peroxide solution, by means of the heating of cover 20 or 30. For example the substrate 100 is brought to a temperature which lies up to 10° C. above, in particular 1° C. to 5° C., and particularly preferably 3° C., above the temperature of the hydrogen peroxide solution 11. Hence, the silicon surfaces are exposed to the action of the hydrogen peroxide-steam mixture 15, thus oxidized and hydrophilized. Generally, a reaction period of 5 minutes to 20 minutes may be suitable for this. In particular a reaction period of 10 minutes is suitable, wherein after this reaction time, complete hydrophilization and purification of the silicon surfaces to be treated is usually already achieved.

1. A method for creating hydrophilic surfaces or surface regions on one or more silicon surfaces of a substrate, comprising:
heating an aqueous hydrogen peroxide solution so as to create a vapor phase of hydrogen peroxide in a reactor; and
exposing the one or more silicon surfaces of the substrate to the vapor phase.

2. The method as claimed in claim 1, wherein the step of heating the aqueous hydrogen peroxide solution includes heating the aqueous hydrogen peroxide solution to a first temperature, the method further comprising:
heating the substrate to a second temperature which is greater than the first temperature.

3. The method as claimed in claim 2, wherein the second temperature is greater than 1-10° C. in comparison to the first temperature.

4. The method as claimed in claim 2, wherein the second temperature is greater than 1-5° C. in comparison to the first temperature.

5. The method as claimed in claim 1, wherein the step of heating the aqueous hydrogen peroxide solution includes heating the aqueous hydrogen peroxide solution to 30-90° C.

6. The method as claimed in claim 1, wherein the step of heating the aqueous hydrogen peroxide solution includes heating the aqueous hydrogen peroxide solution to 40-60° C.

7. The method as claimed in claim 1, wherein the aqueous hydrogen peroxide solution is a 5-85% strength solution.

8. The method as claimed in claim 1, wherein the aqueous hydrogen peroxide solution is a 30% strength solution.

9. The method as claimed in claim 1, further comprising:
prior to the exposing step, orienting the one or more silicon surfaces of the substrate so as to face downwards in the reactor.

10. The method as claimed in claim 1, wherein the exposing step includes exposing the one or more silicon surfaces of the substrate to the vapor phase for 5-20 minutes.

11. The method as claimed in claim 1, wherein the exposing step includes exposing the one or more silicon surfaces of the substrate to the vapor phase for 10 minutes.

12. The method as claimed in claim 1, wherein the substrate is a silicon microarray wafer with one or more trench cells.

13. The method as claimed in claim 1, wherein the substrate is a microfluidic device configured for lab-on-chip applications.

14. A substrate having the hydrophilic surface or surface regions produced according to the method as claimed in claim 1.
